(19) United States
(12) Patent Application Publication
(10) Pub. No.: US 2026/0173289 A1
(43) Pub. Date: Jun. 18, 2026

(54) COVER PANEL INCLUDING INSERT, DISPLAY DEVICE, AND ELECTRONIC DEVICE INCLUDING THE SAME

(71) Applicant: SAMSUNG DISPLAY CO., LTD., YONGIN-SI (KR)

(72) Inventor: SEDAE KI, Yongin-si (KR)

(21) Appl. No.: 19/341,699

(22) Filed: Sep. 26, 2025

(30) Foreign Application Priority Data
Dec. 13, 2024 (KR) 10-2024-0185794

(51) Int. Cl. H05K 5/03; B32B 3/30; B32B 5/18; B32B 7/022; B32B 7/12; B32B 17/06

(52) U.S. Cl. CPC H05K 5/03; B32B 3/30; B32B 5/18; B32B 7/022; B32B 7/12; B32B 17/066; B32B 2307/212; B32B 2307/536; B32B 2307/56; B32B 2307/7376; B32B 2457/20

(57) ABSTRACT

A cover panel includes a shielding layer including a first area and a second area surrounding the first area, a lower adhesive layer disposed on the shielding layer, a cushion layer disposed on the lower adhesive layer, an upper adhesive layer disposed on the cushion layer, a trench formed in the first area, and an insert disposed in the trench. The trench penetrates from an upper surface of the upper adhesive layer to an upper surface of the lower adhesive layer. The insert includes a material different from a material of the cushioning layer, a material of the upper adhesive layer, and a material of the lower adhesive layer.

### CROSS-REFERENCE TO RELATED APPLICATION

This non-provisional patent application claims priority under 35 U.S.C. § 119 to Korean Patent Application No. 10-2024-0185794, filed on Dec. 13, 2024 in the Korean Intellectual Property Office, the disclosure of which is incorporated by reference herein in its entirety.

### TECHNICAL FIELD

The present disclosure relates to a cover panel and, more specifically, to a cover panel including an insert, a display device, and an electronic device including the same.

### DISCUSSION OF THE RELATED ART

With the development of the information society, the demand for display devices in various forms for displaying images is increasing. There is a growing demand for display devices in various forms, such as foldable, wearable, and curved displays, to meet various and diverse user needs and application scenarios. For example, such display devices are applied to various electronic devices, such as smartphones, digital cameras, laptops, navigation devices, and smart televisions. The display device may include a display panel for displaying an image and a sound generator for providing sound.

### SUMMARY

Embodiments of the present disclosure provide a cover panel with enhanced vibration transmission rate. Embodiments of the present disclosure provide a display device with enhanced intensity of sound or haptic. Embodiments of the present disclosure provide an electronic device with enhanced intensity of sound or haptic.

Additional features of the inventive concepts are set forth in the description which follows, and in part are apparent from the description, or may be learned by practice of the inventive concepts.

A cover panel according to an embodiment includes a shielding layer including a first area and a second area surrounding the first area, a lower adhesive layer disposed on the shielding layer, a cushion layer disposed on the lower adhesive layer, an upper adhesive layer disposed on the cushion layer, a trench formed in the first area, and an insert disposed in the trench. The trench may penetrate the upper adhesive layer and the cushion layer. The insert may include a material different from a material of the cushioning layer, a material of the upper adhesive layer, and a material of the lower adhesive layer.

In an embodiment, a hardness of the insert may be greater than a hardness of the cushion layer, a hardness of the upper adhesive layer, and a hardness of the lower adhesive layer.

In an embodiment, a thickness of the insert in the first area may be greater than a sum of a thickness of the upper adhesive layer, a thickness of the cushion layer in the second area, and a thickness of the lower adhesive layer.

In an embodiment, an outer side surface of the insert may contact an inner side surface of the trench.

In an embodiment, a lower surface of the insert may be spaced apart from an upper surface of the shielding layer. The lower adhesive layer may be disposed between the lower surface of the insert and the upper surface of the shielding layer.

In an embodiment, in the first area, the lower surface of the insert may contact an upper surface of the lower adhesive layer.

In an embodiment, a thickness of the lower adhesive layer in the first area may be less than a thickness of the lower adhesive layer in the second area.

In an embodiment, a first distance between a lower surface of the shielding layer and the lower surface of the insert in the first area may be less than a second distance between the lower surface of the shielding layer and an upper surface of the lower adhesive layer in the second area, and the first distance may be greater than a third distance between the lower surface of the shielding layer and a lower surface of the lower adhesive layer in the second area.

In an embodiment, a thickness of the lower adhesive layer in the first area may be equal to a thickness of the lower adhesive layer in the second area.

In an embodiment, the trench may penetrate the lower adhesive layer. A lower surface of the insert may contact an upper surface of the shielding layer.

In an embodiment, a portion of a side surface of the insert may contact a side surface of the lower adhesive layer.

In an embodiment, the cover panel may further include a first support layer disposed between the upper adhesive layer and the cushion layer, and a first intermediate adhesive layer disposed between the first support layer and the cushion layer. The trench may penetrate the first support layer and the first intermediate adhesive layer in the first area. A thickness of the insert in the first area may be greater than a sum of a thickness of the upper adhesive layer in the second area, a thickness of the first support layer in the second area, a thickness of the first intermediate adhesive layer in the second area, and a thickness of the cushion layer in the second area.

In an embodiment, the cover panel may further include a second support layer disposed between the lower adhesive layer and the cushion layer, and a second intermediate adhesive layer disposed between the second support layer and the cushion layer. The trench may penetrate the second support layer and the second intermediate adhesive layer in the first area. The thickness of the insert in the first area may be greater than a sum of the thickness of the upper adhesive layer in the second area, the thickness of the first support layer in the second area, the thickness of the first intermediate adhesive layer in the second area, the thickness of the cushion layer in the second area, a thickness of the second intermediate adhesive layer in the second area, and a thickness of the second support layer in the second area.

In an embodiment, the trench and the insert may each have a rectangular cross-sectional shape.

In an embodiment, the trench and the insert may each have a trapezoidal cross-sectional shape.

In an embodiment, the cover panel further includes a plurality of trenches spaced apart from each other in the first area, and a plurality of inserts respectively disposed in the plurality of trenches.

A display device according to an embodiment includes a cover panel including a first area and a second area surrounding the first area, a display panel disposed on the cover panel and including a plurality of pixels, and a sound generator disposed under the cover panel in the first area, and configured to generate vibration to the display panel. The cover panel includes a shielding layer, a cushion layer disposed on the lower adhesive layer, an upper adhesive layer disposed on the cushion layer, a trench formed in the first area, and an insert disposed in the trench in the first area. The trench penetrates the upper adhesive layer and the cushion layer. The insert includes a material different from a material of the cushioning layer, a material of the upper adhesive layer, and a material of the lower adhesive layer.

In an embodiment, a hardness of the insert may be greater than a hardness of the cushion layer, a hardness of the upper adhesive layer, and a hardness of the lower adhesive layer.

In an embodiment, the sound generator may overlap the insert in the first area.

An electronic device according to an embodiment includes a cover panel including a first area and a second area surrounding the first area, a display panel disposed on the cover panel and including a plurality of pixels, a sound generator disposed in the first area under the cover panel, and configured to generate vibration transmitted to the display panel, and a housing configured to contain the cover panel, the display panel, and the sound generator. The cover panel includes a shielding layer, a cushion layer disposed on the lower adhesive layer, an upper adhesive layer disposed on the cushion layer, a trench formed in the first area, and an insert disposed in the trench in the first area. The trench penetrates the upper adhesive layer and the cushion layer. The insert includes a material different from a material of the cushioning layer, a material of the upper adhesive layer, and a material of the lower adhesive layer.

The display device according to embodiments may include the display panel, the cover panel disposed under the display panel, and the sound generator disposed under a portion of the cover panel. The sound generator may vibrate the display panel to generate sound or haptic. In the cover panel, layers having relatively small hardness (e.g., an adhesive layer and a cushion layer) may be removed in the portion of the cover panel where the sound generator is disposed to form a trench, and an insert having relatively large hardness may be disposed in the trench. Accordingly, the cover panel may properly transmit vibration generated by the sound generator to the display panel, and can minimize loss of sound pressure when outputting sound through the vibration of the display panel. Accordingly, the intensity of sound or haptic output by the display device and the electronic device including the same may be enhanced.

It is to be understood that both the foregoing general description and the following detailed description are exemplary and explanatory and are intended to provide further explanation of the invention as claimed.

### BRIEF DESCRIPTION OF THE DRAWINGS

The accompanying drawings are included to provide a further understanding of the invention and are incorporated in the specification. The drawings illustrate embodiments of the invention and in combination with the detailed description explain the invention.

FIG. 1 is a perspective view illustrating an electronic device according to an embodiment.

FIG. 2 is a block diagram illustrating an electronic device according to an embodiment.

FIG. 3 is a cross-sectional view illustrating an electronic device according to an embodiment.

FIG. 4 is a cross-sectional view illustrating an example of a display panel included in the electronic device of FIG. 3.

FIG. 5 is a cross-sectional view illustrating an example of a cover panel and a sound generator included in the electronic device of FIG. 3.

FIG. 6 is a cross-sectional view illustrating an example of a sound generator of FIG. 5.

FIG. 7 illustrates the vibration of a vibration layer disposed between first branch electrodes and second branch electrodes of the sound generator.

FIG. 8 and FIG. 9 are cross-sectional views illustrating the vibration of the display panel using the sound generator of FIG. 7.

FIG. 10 is a graph illustrating an amplitude of vibration measured on an upper surface of a display panel.

FIG. 11 is a graph illustrating a sound pressure level by frequency of sound generated from a display device.

FIG. 12 and FIG. 13 are cross-sectional views illustrating an example of a method for manufacturing the cover panel of FIG. 5.

FIG. 14 is a cross-sectional view illustrating an example of a cover panel and a sound generator included in the electronic device of FIG. 3.

FIG. 15 is a cross-sectional view illustrating an example of a cover panel and a sound generator included in the electronic device of FIG. 3.

FIG. 16 is a cross-sectional view illustrating an example of a cover panel and a sound generator included in the electronic device of FIG. 3.

FIG. 17 is a cross-sectional view illustrating an example of a cover panel and a sound generator included in the electronic device of FIG. 3.

FIG. 18 is a cross-sectional view illustrating an example of a cover panel and a sound generator included in the electronic device of FIG. 3.

FIG. 19 is a cross-sectional view illustrating an of a sound generator of FIG. 5.

FIG. 20 and FIG. 21 are cross-sectional views illustrating the vibration of the display panel using the sound generator of FIG. 19.

FIG. 22 is a drawing illustrating a vehicle including an electronic device according to an embodiment.

FIG. 23 is a block diagram illustrating an electronic device according to an embodiment.

### DETAILED DESCRIPTION

Various example embodiments are described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure is thorough and complete, and fully conveys the scope of the present inventive concept to those skilled in the art. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

In the disclosure, various modifications can be made, various forms can be used, and specific embodiments may be illustrated in the drawings and described in detail in the text. However, this is not necessarily intended to limit the disclosure to a specific form disclosed, and it is understood that all changes, equivalents, or substitutes which fall in the spirit and technical scope of the disclosure should be included.

It is understood that, although the terms first, second, third, etc. may be used herein to describe various elements, these elements should not be necessarily limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It is understood that when an element is referred to as being “connected” or “coupled” to another element, the element can be directly connected or coupled to the other element or intervening element(s) may be present. In contrast, when an element is referred to as being “directly connected” or “directly coupled” to another element, there are no intervening elements present therebetween. Other words used to describe the relationship between elements should be interpreted in a similar manner (e.g., “between” versus “directly between,” “adjacent” versus “directly adjacent,” etc.).

The terminology used herein is for the purpose of describing particular example embodiments and is not necessarily intended to be limiting of the present inventive concept. As used herein, the singular forms “a,” “an” and “the” are intended to include the plural forms as well, unless the context clearly indicates otherwise. It is further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe the relationship of one element to another element as illustrated in the figures. It is understood that relative terms are intended to encompass different orientations of the device in addition to the orientation depicted in the figures. For example, if the device in one of the figures is turned over, elements described as being on the “lower” side of other elements would then be oriented on “upper” side of the other elements. The term “lower,” can therefore, encompasses both an orientation of “lower” and “upper,” based on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Hereinafter, embodiments are described in detail with reference to the accompanying drawings. The same reference numerals are used for the same components in the drawings, and to the extent that an element is not described in detail with respect to a figure, it may be understood that the element is at least similar to a corresponding element that has been described elsewhere within the present disclosure.

Embodiments of the present disclosure provide a cover panel (e.g., a stacked structure) for a display device, the cover panel includes a trench is formed in a first area of the cover panel and filled with an insert having greater hardness than surrounding adhesive or cushion layers. This configuration improves transmission of vibration from a sound generator disposed beneath the cover panel, resulting in enhanced acoustic or haptic performance.

The trench vertically penetrates through the adhesive layers, the cushion layer, and support layers, with the insert disposed in the trench. The insert may be formed of a material such as a polymer, resin, or metal having a higher stiffness than the adhesive and cushion layers. By reducing the thickness or fully removing vibration-absorbing layers in the first area and replacing the layers in the first area with the insert, the cover panel can effectively transfer vibration to the overlying display panel.

In some embodiments, the insert may extend down to or contacts the lower adhesive layer, or further to the shielding layer. In some embodiments, the insert may be disposed at a level between the adhesive layer and the shielding layer. The insert and trench may each have a rectangular or trapezoidal cross-section, and multiple inserts may be arranged within a single first area or distributed across multiple first areas. Accordingly, by structurally modifying the stacked layers of the cover panel in a localized region (e.g., the first area) where a sound generator is disposed, the embodiments of the present disclosure can reduce vibrational loss, increase transmission efficiency, and enhance sound pressure output.

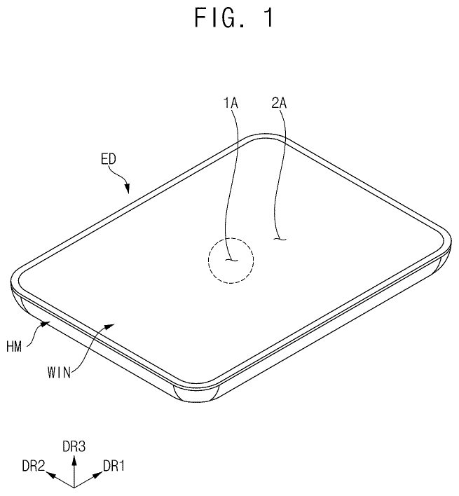

FIG. 1 is a perspective view illustrating an electronic device according to an embodiment.

In the specification, a plane may be represented by a first direction DR1 and a second direction DR2 crossing the first direction DR1. For example, the first direction DR1 and the second direction DR2 may be perpendicular to each other. An electronic device ED and various components or layers may have a thickness extending along a third direction DR3 crossing the plane. For example, the third direction DR3 may be perpendicular to each of the first direction DR1 and the second direction DR2. Hereinafter, the third direction DR3 may be referred to as an upper direction, and a direction opposite to the third direction DR3 may be referred to as a lower direction. The third direction DR3 and the direction opposite to the third direction DR3 may be referred to as a thickness direction (or a vertical direction).

Referring to FIG. 1, an electronic device ED may be a device activated by an electrical signal and may provide a display screen capable of displaying an image in the third direction DR3. For example, the electronic device ED may include a vehicle monitor, a tablet PC, a laptop, a television, a computer monitor, a billboard, a smartphone, a mobile phone, a smart watch, a game console, a head-mounted display, or the similar devices that include the display screen. Although FIG. 1 illustrates that the electronic device ED includes a flat display screen, the electronic device ED may include a curved display screen.

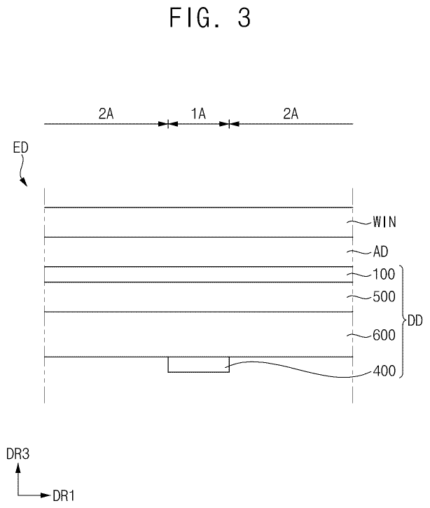

In an embodiment, the electronic device ED may include a window WIN, a housing HM, a display device (e.g., a display device DD of FIG. 3), and a processor. The window WIN and the housing HM may be combined to represent an external appearance of the electronic device ED. The display device may include a display panel (e.g., a display panel 100 of FIG. 3) that displays an image, and a sound generator (e.g., a sound generator 400 of FIG. 3) that vibrates the display panel to generate sound or haptic feedback.

The window WIN may represent an upper surface of the electronic device ED. The window WIN may have light-transmitting properties. For example, the window WU may include a resin film, such as polyimide, ultra-thin glass, or the like. In an embodiment, the window WIN may be omitted.

The housing HM may be combined with the window WIN. The housing HM may be combined with the window WIN to provide an internal space. The display device and the processor may be disposed in the internal space provided between the housing HM and the window WIN. Various components, such as an optical film, a cushion layer, a heating layer, a memory device, a storage device, an I/O device, a power supply, or other components, may be further disposed in the internal space. The housing HM may include a material having relatively high rigidity. The housing HM may stably protect the components disposed in the internal space from external impact.

As illustrated in FIG. 1, the electronic device ED may include a first area 1A and a second area 2A. The first area 1A may be a region including the sound generator, and the second area 2A may be a region (or a remaining region) that does not include the sound generator. In an embodiment, the first area 1A may be surrounded by the second area 2A in a plan view. Although FIG. 1 illustrates that the electronic device ED includes one first area 1A, the number of the first area 1A may be variously changed based on the number of the sound generator included in the electronic device ED. For example, the electronic device ED may include two or more first areas 1A spaced apart from each other in a plan view, and the second area 2A may surround each of the first areas 1A in a plan view. In addition, although FIG. 1 illustrates that the first area 1A has a circular planar shape, the planar shape of the first area 1A may be variously changed, such as a polygon, an ellipse, or other geometric shapes.

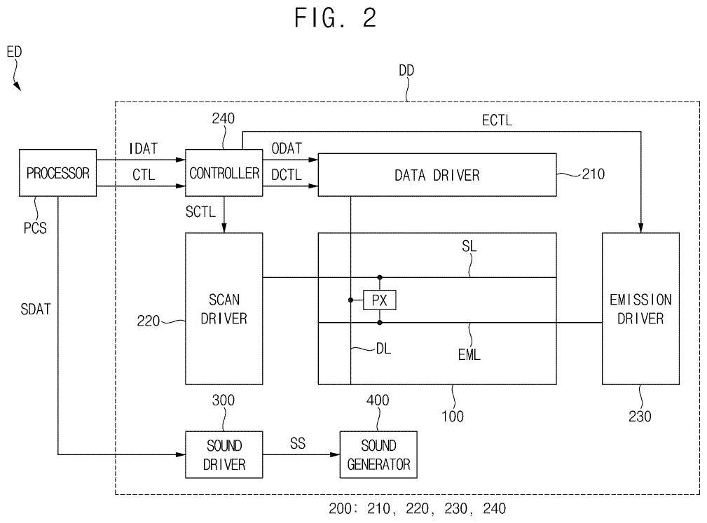

FIG. 2 is a block diagram illustrating an electronic device according to an embodiment.

Referring to FIG. 2, the electronic device ED according to an embodiment may include the processor PCS and the display device DD.

The processor PCS may provide input image data IDAT and sound data SDAT to the display device DD. In an embodiment, the processor PCS may be a microprocessor, a central processing unit (“CPU”), a graphics processing unit (“GPU”), an application processor (“AP”), or another computing element. For example, the processor PCS is an intelligent hardware device, (e.g., a general-purpose processing component, a digital signal processor (DSP), a central processing unit (CPU), a graphics processing unit (GPU), a microcontroller, an application-specific integrated circuit (ASIC), a field programmable gate array (FPGA), a programmable logic device, a discrete gate or transistor logic component, a discrete hardware component, or a combination thereof. In some cases, processor PCS is configured to operate a memory array using a memory controller. In other cases, a memory controller is integrated into the processor PCS. In some cases, the processor PCS is configured to execute computer-readable instructions stored in a memory to perform various functions. In some embodiments, the processor PCS includes special-purpose components for modem processing, baseband processing, digital signal processing, or transmission processing.

The display device DD may include the display panel 100, a panel driver 200, a sound driver 300, and the sound generator 400. In one aspect, the panel driver 200 includes the data driver 210, the scan driver 220, the emission driver 230, and the controller 240.

The display panel 100 may include pixels PX and may display an image. The display panel 100 may include a display area that displays an image and a peripheral area surrounding the display area. The display panel 100 may include scan lines SL, data lines DL, emission lines EML, and the pixels PX. The pixels PX may be electrically connected to the scan lines SL, the data lines DL, and the emission lines EML.

The panel driver 200 may drive the display panel 100 based on the input image data IDAT received from the processor PCS. In an embodiment, the panel driver 200 may include a data driver 210, a scan driver 220, an emission driver 230, and a driving controller 240. The data driver 210 may be configured to provide the data signals to the pixels PX via the data line DL. The scan driver 220 may be configured to provide the scan signals to the pixels PX via the scan line SL. The emission driver 230 may be configured to provide emission signals to the pixels PX via the emission line EML. The driving controller 240 may control the data driver 210, the scan driver 220, and the emission driver 230. The driving controller 240 may be configured to coordinate timing between the panel driver 200 and the sound driver 300 to ensure synchronization between image display and sound output.

The data driver 210 may generate the data signals based on output image data ODAT and a data control signal DCTL generated by the driving controller 240, and may provide the data signals to the pixels PX through one or more data lines DL. In an embodiment, the data control signal DCTL may include an output data enable signal, a horizontal start signal, and a load signal, but the present invention is not necessarily limited thereto. In an embodiment, the data driver 210 and the driving controller 240 may be implemented as a single integrated circuit, and the single integrated circuit may be referred to as a timing controller embedded data driver (“TED”) integrated circuit. In an embodiment, the data driver 210 and the driving controller 240 may be implemented as separate integrated circuits. In some embodiments, one or more of the data driver 210, scan driver 220, and emission driver 230 may be implemented as a single integrated circuit or as discrete components.

The scan driver 220 may generate the scan signals based on a scan control signal SCTL generated by the driving controller 240, and may sequentially provide the scan signals to the pixels PX through the scan lines on a row-by-row basis. In an embodiment, the scan control signal SCTL may include a scan start signal, a scan clock signal, or other signals, but the present invention is not necessarily limited thereto.

The emission driver 230 may generate the emission signals based on an emission control signal ECTL generated by the driving controller 240, and may sequentially provide the emission signals to the pixels PX through the emission lines EML on a row-by-row basis. In an embodiment, the emission control signal ECTL may include an emission start signal, an emission clock signal, other timing-related control signals, but the present invention is not necessarily limited thereto.

The driving controller 240 may receive the input image data IDAT and an input control signal CTL from the processor PCS. In an embodiment, the input control signal CTL may include a vertical synchronization signal, a horizontal synchronization signal, an input data enable signal, a master clock signal, or other synchronization-related control signals, but the present invention is not necessarily limited thereto. The driving controller 240 may generate the output image data ODAT, the data control signal DCTL, the scan control signal SCTL, and the emission control signal ECTL based on the input image data IDAT and the input control signal CTL. The driving controller 240 may control the data driver 210 by providing the output image data ODAT and the data control signal DCTL to the data driver 210, may control the scan driver 220 by providing the scan control signal SCTL to the scan driver 220, and may control the emission driver 230 by providing the emission control signal ECTL to the emission driver 230. In some cases, a feedback circuit may be included to monitor performance or vibration characteristics of the display panel 100, allowing dynamic adjustment of control signals to optimize the output (e.g., image output and/or sound).

The sound driver 300 may drive the sound generator 400 based on the sound data SDAT generated by the processor PCS. In an embodiment, the sound driver 300 may convert the sound data SDAT, which is digital data, into a sound signal SS, which is an analog signal. The sound driver 300 may output the sound signal SS to the sound generator 400. The sound signal SS may include one or more driving voltages.

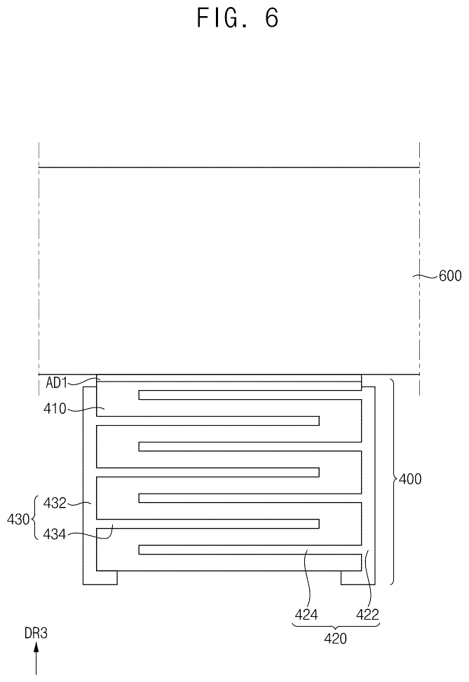

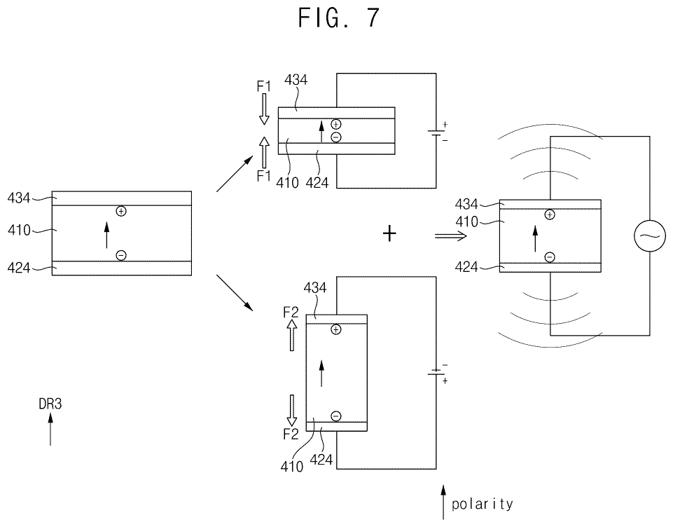

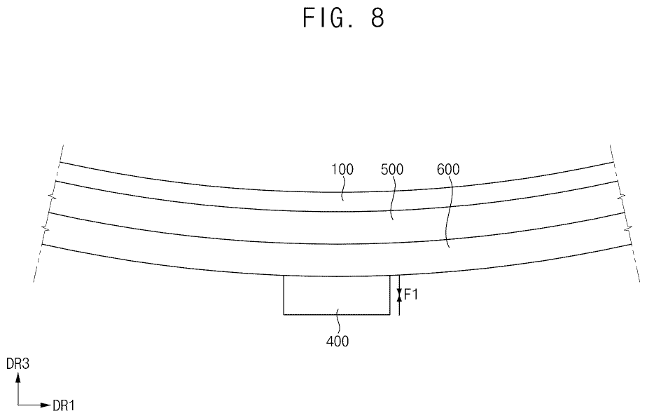

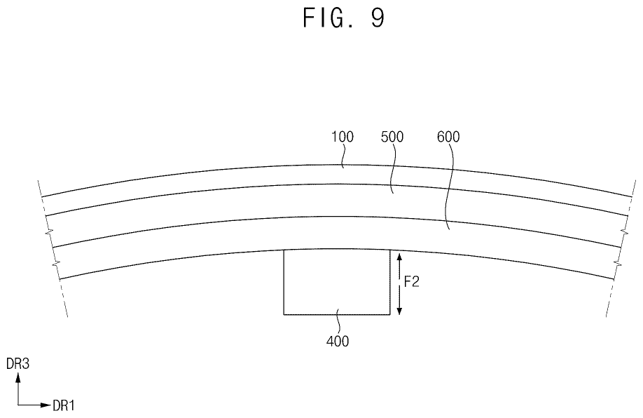

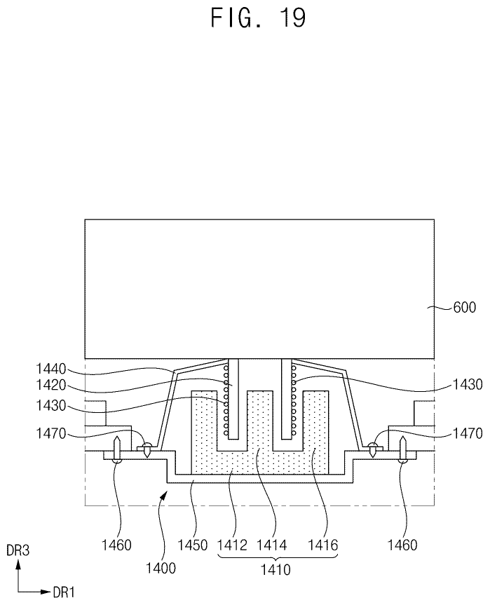

The sound generator 400 may be a vibration device capable of vibrating the display panel 100 in the thickness direction (e.g., the third direction DR3 and the direction opposite to the third direction DR3 of FIG. 1) based on the sound signal SS generated by the sound driver 300 (see FIGS. 8 and 9). In an embodiment, the sound generator 400 may be a piezoelectric element or piezoelectric actuator for vibrating the display panel 100 using a piezoelectric material that contracts or expands based on voltage (see FIGS. 6 and 7). In an embodiment, the sound generator 400 may be an exciter for vibrating the display panel 100 by generating a magnetic force using a voice coil (see FIGS. 19 to 21).

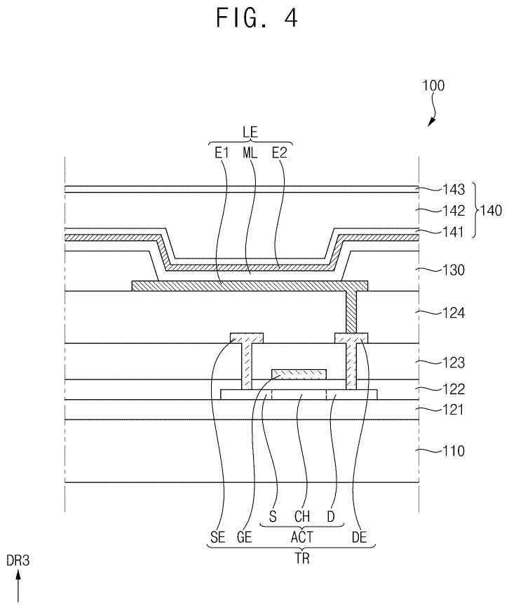

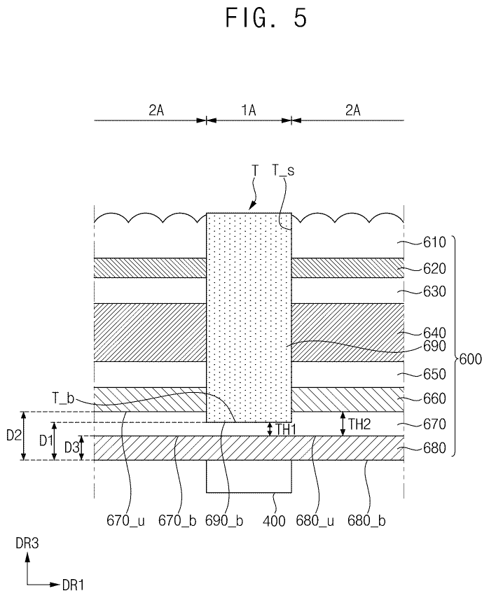

FIG. 3 is a cross-sectional view illustrating an electronic device according to an embodiment. FIG. 4 is a cross-sectional view illustrating an example of a display panel included in the electronic device of FIG. 3. FIG. 5 is a cross-sectional view illustrating an example of a cover panel and a sound generator included in the electronic device of FIG. 3. FIGS. 3-5 illustrate the layered structure and functional interaction between the image display component (e.g., the display panel 100) and the sound generation element (e.g., the sound generator 400).

Referring to FIG. 3, the electronic device ED may include the window WIN, the display device DD, and an adhesive layer AD disposed between the window WIN and the display device DD. The display device DD may include the display panel 100, a protective film 500, a cover panel 600, and the sound generator 400. The electronic device ED may include the first area 1A and the second area 2A. Each of the window WIN, the display panel 100, the protective film 500, and the cover panel 600 may include the first area 1A and the second area 2A. In some embodiments, the second area 2A may surround the first area 1A.

The window WIN may be disposed on the display panel 100 (e.g., in the third direction DR3, corresponding to the upper direction). The adhesive layer AD may be disposed between the window WIN and the display panel 100. The adhesive layer AD may attach (e.g., bond or couple_ the display panel 100 and the window WIN to each other. In an embodiment, the adhesive layer AD may include an optical clear adhesive (“OCA”), a pressure sensitive adhesive (“PSA”), a photocurable resin, a thermosetting resin, or other optically transmissive bonding materials. The adhesive materials may be used alone or in combination with each other. In an embodiment, other functional layers, such as an anti-reflection layer, a touch sensing layer, or a polarizing film may be disposed between the window WIN and the display panel 100.

Hereinafter, an example of a cross-sectional structure of the display panel 100 is described with reference to FIG. 4. Referring to FIG. 4, the display panel 100 may include a substrate 110, a buffer layer 121, a transistor TR, first to third insulating layers 122, 123, and 124, a pixel defining layer 130, a light emitting element LE, and an encapsulation layer 140.

The substrate 110 may form a base for the display panel 100. The substrate 110 may be an insulating substrate including or formed of a transparent or a non-transparent material. The substrate 110 may be flexible or rigid. The substrate 110 may have a single layer structure or a multi-layer structure in which multiple layers including different materials are disposed in a stacking configuration.

The buffer layer 121 may be disposed on the substrate 110. The buffer layer 121 may prevent or reduce impurities, such as oxygen or moisture, from penetrating into an upper portion of the substrate 110 through the substrate 110. The buffer layer 121 may include an inorganic material, such as a silicon compound, a metal oxide, or other moisture-barrier materials. For example, the buffer layer 121 may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or other compounds. The above-listed materials may be used alone or in combination with each other. The buffer layer 121 may have a single layer structure or a multi-layer structure including a plurality of insulating layers.

The transistor TR may be disposed on the buffer layer 121. The transistor TR may include an active layer ACT, a gate electrode GE, a first contact electrode SE, and a second contact electrode DE.

The active layer ACT may be disposed on the buffer layer 121. The active layer ACT may include an oxide semiconductor, a silicon semiconductor, an organic semiconductor, or other materials suitable for thin-film transistors. For example, the oxide semiconductor may include at least one of oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or other forms of silicon films. The active layer ACT may include a first contact area S, a second contact area D, and a channel area CH disposed between the first contact area S and the second contact area D. Each of the first contact area S and the second contact area D may have higher conductivity than a conductivity of the channel area CH.

The first insulating layer 122 may be disposed on the active layer ACT. The first insulating layer 122 may cover the active layer ACT and disposed on the buffer layer 121. The first insulating layer 122 may include an inorganic insulating material. In some cases, an upper surface of the first insulating layer 122 may be at a higher level than an upper surface of the active layer ACT. In some cases, the first insulating layer 122 may cover side surfaces of the active layer ACT.

The gate electrode GE may be disposed on the first insulating layer 122. The gate electrode GE may overlap the channel area CH of the active layer ACT. The gate electrode GE may include a conductive material, such as a metal, an alloy, a conductive metal nitride, a conductive metal oxide, a transparent conductive material, or other conductive materials. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), and iridium (Ir). In some cases, for example, the gate electrode GE may include alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. The aforementioned conductive materials may be used alone or in combination with each other. The gate electrode GE may have a single layer structure or a multi-layer structure including a plurality of conductive layers.

The second insulating layer 123 may be disposed on the gate electrode GE. The second insulating layer 123 may cover the gate electrode GE and may be disposed on the first insulating layer 122. The second insulating layer 123 may include an inorganic insulating material. In some cases, for example, the second insulating layer 123 may cover an upper surface and side surfaces of the gate electrode GE.

The first contact electrode SE and the second contact electrode DE may be disposed on the second insulating layer 123. The first contact electrode SE and the second contact electrode DE may be connected to the first contact area S and the second contact area D of the active layer ACT, respectively. The electrical connection may be established through contact holes or vias penetrating the second insulating layer 123 and first insulating layer 122. Each of the first contact electrode SE and the second contact electrode DE may include a conductive material.

The third insulating layer 124 may be disposed on the first contact electrode SE and the second contact electrode DE. The third insulating layer 124 may include an organic insulating material. For example, the third insulating layer 124 may include a photoresist, a polyacryl-based resin, a polyimide-based resin, a polyamide-based resin, a siloxane-based resin, an acrylic resin, an epoxy-based resin, or the like. The organic insulating materials listed above may be used alone or in combination with each other. In some cases, the third insulating layer 124 may serve as a planarization layer or interlayer dielectric to form a flat upper surface and electrically isolate other overlaying components.

The light emitting element LE may be disposed on the third insulating layer 124. The light emitting element LE may include a first electrode E1, an intermediate layer ML, and a second electrode E2.

The first electrode E1 may be disposed on the third insulating layer 124. The first electrode E1 may include a conductive material. The first electrode E1 may be connected to the second contact electrode DE through a contact hole formed in the third insulating layer 124. Accordingly, the first electrode E1 may be electrically connected to the transistor TR. For example, the first electrode E1 may be an anode of the light emitting element LE.

The pixel defining layer 130 may be disposed on the first electrode E1. The pixel defining layer 130 may cover a peripheral portion of the first electrode E1 and may define a pixel opening that exposes a central portion of the first electrode E1. The pixel opening may represent an emission area. The pixel defining layer 130 may include an organic insulating material. In an embodiment, the pixel defining layer 130 may further include an inorganic material or an organic material including (or containing) a light blocking material having a black color. In some cases, the pixel defining layer 130 may cover at least portions of the ends of the first electrode E1.

The intermediate layer ML may be disposed on the first electrode E1 and the pixel defining layer 130. A portion of the intermediate layer ML may be disposed in the pixel opening defined by the pixel defining layer 130. In an embodiment, the intermediate layer ML may include a first functional layer including an organic material, an emission layer disposed on the first functional layer and including an emission material, and a second functional layer disposed on the emission layer and including an organic material. For example, the first functional layer may include a hole injection layer, a hole transport layer, or a combination thereof. The second functional layer may include an electron transport layer, an electron injection layer, or a combination thereof.

In an embodiment, the emission layer may include at least one of an organic light emitting material or a quantum dot, but the present invention is not necessarily limited thereto. Other light-emitting materials may also be used based on a specification of the display panel 100.

In an embodiment, the organic light emitting material may include a low molecular weight organic compound or a high molecular weight organic compound. Examples of the low molecular weight organic compound may include copper phthalocyanine, N,N′-diphenylbenzidine, tris-(8-hydroxyquinoline)aluminum, or the like. Examples of the high molecular weight organic compound may include poly(3,4-ethylenedioxythiophene), polyaniline, poly-phenylenevinylene, polyfluorene, or the like. The above-listed organic light emitting materials can be used alone or in a combination thereof.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may act as a protection layer preventing the core from being chemically denatured to maintain the semiconductor characteristics of the core. In some cases, the shell may act as a charging layer for imparting electrophoretic characteristics to the quantum dot.

The second electrode E2 may be disposed on the intermediate layer ML. The second electrode E2 may include a conductive material. For example, the second electrode E2 may be a cathode of the light emitting element LE. In some cases, the intermediate layer ML and the second electrode E2 may each have a substantially uniform thickness across the emission area.

The encapsulation layer 140 may be disposed on the second electrode E2. The encapsulation layer 140 may include at least one inorganic encapsulation layer and at least one organic encapsulation layer. In an embodiment, the encapsulation layer 140 may include a first inorganic encapsulation layer 141 disposed on the second electrode E2, an organic encapsulation layer 142 disposed on the first inorganic encapsulation layer 141, and a second inorganic encapsulation layer 143 disposed on the organic encapsulation layer 142.

Referring again to FIG. 3, the protective film 500 may be disposed under the display panel 100 (e.g., in the direction opposite to the third direction DR3, which corresponds to the lower direction). The protective film 500 may be disposed on a lower surface of the display panel 100. For example, an adhesive layer may be disposed between the display panel 100 and the protective film 500 to bond the two layers together while maintaining optical and mechanical integrity.

The protective film 500 may serve to support and/or protect the components of the display panel 100. The protective film 500 may include plastic, glass, an organic or inorganic composite material, or other flexible or rigid substrates suitable for mechanical protection. For example, the protective film 500 may include polyethylene terephthalate (“PET”), but the present invention is not necessarily limited thereto. In an embodiment, the protective film 500 may be omitted. For example, the display panel 100 may be directed disposed on a cover panel 600.

The cover panel 600 may be disposed under the display panel 100 (e.g., in the direction opposite to the third direction DR3, which corresponds to the lower direction). The cover panel 600 may be disposed under the protective film 500 (e.g., in the direction opposite to the third direction DR3). For example, an upper surface of the cover panel 600 may be attached to a lower surface of the protective film 500.

The cover panel 600 may protect the display panel 100 from an external environment under the display panel 100 (e.g., from physical impact, electromagnetic interference, or vibrational noise). In addition, the cover panel 600 may diffuse heat generated from the display panel 100, and may reduce or prevent transfer of heat to the display panel 100 generated from electronic components, such as a processor, a battery, a memory, or other internal hardware, which may be located under the display panel 100 in the electronic device ED. The sound generator 400 may be disposed in the first area 1A under the cover panel 600.

Hereinafter, an example of a cross-sectional structure of the cover panel 600 is described with further reference to FIG. 5. Referring to FIG. 3 and FIG. 5, the cover panel 600 may include an upper adhesive layer 610, a first support layer 620, a first intermediate adhesive layer 630, a cushion layer 640, a second intermediate adhesive layer 650, a second support layer 660, a lower adhesive layer 670, a shielding layer 680, and an insert 690.

The upper adhesive layer 610 may be an adhesive layer for attachment to the protective film 500. For example, an upper surface of the upper adhesive layer 610 may be attached to the lower surface of the protective film 500, In an embodiment, an embossed pattern may be formed in the upper surface of the upper adhesive layer 610. The embossed pattern may discharge air bubbles to the outside during the attaching process of the cover panel 600. In an embodiment, the upper adhesive layer 610 may include a pressure-sensitive adhesive (PSA). The upper adhesive layer 610 may be disposed on the first support layer 620, the first intermediate adhesive layer 630, the cushion layer 640, the second intermediate adhesive layer 650, the second support layer 660, the lower adhesive layer 670, and the shielding layer 680.

The first support layer 620 may be disposed under the upper adhesive layer 610. The first support layer 620 may be disposed on the first intermediate adhesive layer 630, the cushion layer 640, the second intermediate adhesive layer 650, the second support layer 660, the lower adhesive layer 670, and the shielding layer 680. The first support layer 620 may be disposed between the upper adhesive layer 610 and the cushion layer 640. The cushion layer 640 may be disposed under the first support layer 620. The cushion layer 640 may be disposed on the second intermediate adhesive layer 650, the second support layer 660, the lower adhesive layer 670, and the shielding layer 680. The second support layer 660 may be disposed under the cushion layer 640. The second support layer 660 may be disposed on the lower adhesive layer 670 and the shielding layer 680. The second support layer 660 may be disposed between the lower adhesive layer 670 and the cushion layer 640. In some embodiments, first intermediate adhesive layer 630 may be disposed between the first support layer 620 and the cushion layer 640. However, embodiments are not necessarily limited thereto.

Each of the first support layer 620 and the second support layer 660 may be a plastic layer including a resin, such as PET, polyimide (“PI”), or another polymer suitable for mechanical reinforcement or thermal stability. For example, the first support layer 620 may include PET, and the second support layer 660 may include PI, but the present invention is not necessarily limited thereto.

In an embodiment, at least one of the first support layer 620 and the second support layer 660 may be colored. For example, the first support layer 620 may be colored. For example, the first support layer 620 may be black. The first support layer 620 may absorb light incident on an upper surface of the first support layer 620.

The cushion layer 640 may be a porous layer formed of a material, such as polyurethane, polyethylene, or other compressible polymer suitable for impact absorption. The cushion layer 640 may include a foam resin. The cushion layer 640 may also include an elastomer. The cushion layer 640 may be provide mechanical cushioning within the cover panel 600.

The first intermediate adhesive layer 630 may be disposed between the first support layer 620 and the cushion layer 640, and the second intermediate adhesive layer 650 may be disposed between the cushion layer 640 and the second support layer 660. The first intermediate adhesive layer 630 may attach (or bond) the first support layer 620 and the cushion layer 640 to each other, and the second intermediate adhesive layer 650 may attach (or bond) the cushion layer 640 and the second support layer 660 to each other. In an embodiment, each of the first intermediate adhesive layer 630 and the second intermediate adhesive layer 650 may include a pressure-sensitive adhesive (PSA).

The shielding layer 680 may be disposed under the second support layer 660. The shielding layer 680 may prevent or reduce electromagnetic waves, static electricity, noise, or electromagnetic noise from flowing from an external environment under the cover panel 600 to the display panel 100. In addition, the shielding layer 680 may dissipate heat generated from the electronic components, such as the processor, the battery, the memory, or other electronic components. The shielding layer 680 may be a metal layer including a metal having excellent thermal conductivity along with shielding performance, such as copper (Cu), aluminum (Al), or other thermally and electrically conductive elements.

The lower adhesive layer 670 may be disposed between the second support layer 660 and the shielding layer 680. The lower adhesive layer 670 may be disposed on the shielding layer 680. The lower adhesive layer 670 may attach (or bond) the second support layer 660 and the shielding layer 680 to each other. In an embodiment, the lower adhesive layer 670 may include a pressure-sensitive adhesive (PSA).

The shielding layer 680 may include the first area 1A and the second area 2A. In an embodiment, the shielding layer 680 may be disposed in both the first area 1A and the second area 2A. In some cases, the second area 2A may surround the first area 1A. The configuration of the shielding layer 680 provides continuous electromagnetic and thermal protection across the cover panel 600.

In an embodiment, the cover panel 600 may have a trench T formed in the thickness direction (e.g., in the direction opposite to the third direction DR3) from the upper surface of the cover panel 600 (e.g., the upper surface of the upper adhesive layer 610) in the first area 1A. In some cases, the trench T may be extended to the lower adhesive layer 670. The insert 690 may be disposed in the trench T. The trench T may penetrate at least one of the upper adhesive layer 610, the first support layer 620, the first intermediate adhesive layer 630, the cushion layer 640, the second intermediate adhesive layer 650, the second support layer 660, and the lower adhesive layer 670 extending toward the shielding layer 680 in the thickness direction. In some cases, the trench T may penetrate the aforementioned layers in the first area 1A.

In an embodiment, as illustrated in FIG. 5, the trench T may penetrate each of the upper adhesive layer 610, the first support layer 620, the first intermediate adhesive layer 630, the cushion layer 640, the second intermediate adhesive layer 650, and the second support layer 660 in the thickness direction. For example, each of the upper adhesive layer 610, the first support layer 620, the first intermediate adhesive layer 630, the cushion layer 640, the second intermediate adhesive layer 650, and the second support layer 660 may have a through hole having a width corresponding to the width of the first area 1A. A depth of the trench T may be greater than a sum of a thickness of the upper adhesive layer 610, a thickness of the first support layer 620, a thickness of the first intermediate adhesive layer 630, a thickness of the cushion layer 640, a thickness of the second intermediate adhesive layer 650, and a thickness of the second support layer 660 in the second area 2A.

In an embodiment, inner side surfaces of the upper adhesive layer 610, the first support layer 620, the first intermediate adhesive layer 630, the cushion layer 640, the second intermediate adhesive layer 650, and the second support layer 660 which represent a side surface T_s of the trench T may be aligned with each other.

In an embodiment, the trench T might not be formed in the shielding layer 680. In the first area 1A, a bottom surface T_b of the trench T may be spaced apart from an upper surface 680_u of the shielding layer 680 in the upper direction (e.g., in the third direction DR3). A level of the bottom surface T_b of the trench T may be higher than a level of the upper surface 680_u of the shielding layer 680. For example, the upper surface 680_u of the shielding layer 680 may be generally flat in both the first area 1A and the second area 2A. In some cases, the bottom surface T_b of the trench T may be at a level between an upper surface 670_u of the lower adhesive layer 670 and a lower surface 670_b of the lower adhesive layer 670.

The insert 690 may be disposed in the first area 1A on the shielding layer 680. The insert 690 may be disposed in the trench T. The insert 690 may be inserted in the trench T. The insert 690 may overlap the sound generator 400 in the thickness direction (e.g., the third direction DR3).

The insert 690 may include a material having a relatively high hardness. The insert 690 may include a material different from materials of the upper adhesive layer 610, the first intermediate adhesive layer 630, the cushion layer 640, the second intermediate adhesive layer 650, and the lower adhesive layer 670 which have a relatively low hardness. A hardness of the insert 690 may be greater than a hardness of each of the upper adhesive layer 610, the first intermediate adhesive layer 630, the cushion layer 640, the second intermediate adhesive layer 650, and the lower adhesive layer 670. For example, the insert 690 may include a resin, such as polyimide (PI), polyethylene terephthalate (PET), or may include a metal or an alloy having a relatively high hardness in the first area 1A.

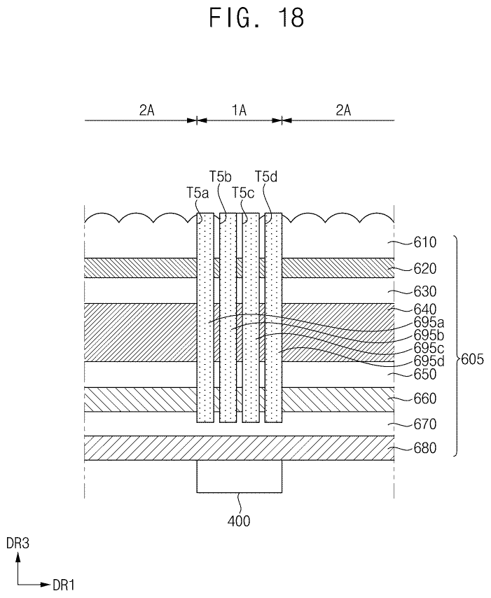

Although FIG. 5 illustrates that the cover panel 600 includes one insert 690, the present invention is not necessarily limited thereto. For example, a plurality of inserts 690 may be disposed corresponding to one sound generator 400 (see FIG. 18), or a plurality of inserts 690 may be disposed respectively corresponding to a plurality of sound generators 400.

The sound generator 400 may be disposed in the first area 1A under the cover panel 600. In an embodiment, the sound generator 400 may be attached (or bonded) to a lower surface 680_b of the shielding layer 680 in the first area 1A. The sound generator 400 may vibrate the cover panel 600, the protective film 500, and the display panel 100 in the thickness direction (e.g., along the third direction DR3).

The cover panel 600 may have a vertically stacked structure in which each layer is disposed in the thickness direction in a sequential manner. From top to bottom, the stacked structure may include the upper adhesive layer 610, the first support layer 620, the first intermediate adhesive layer 630, the cushion layer 640, the second intermediate adhesive layer 650, the second support layer 660, the lower adhesive layer 670, and the shielding layer 680. The insert 690 may be embedded within the trench T formed in the first area 1A, and may extend vertically through a portion of the stacked structure down to a position proximate to, but spaced apart from, the shielding layer 680. For example, the trench T may be extended between upper surface 670_u of the lower adhesive layer 670 and a lower surface 670_b of the lower adhesive layer 670. The insert 690 may occupy a region surrounded laterally by the side surface T_s of the trench and vertically bounded by the bottom surface T_b of the trench. The configuration of the insert 690 and the stacked structure may create a vertical structure that reinforces the stack in the first area 1A and provide efficient vibration transfer from the sound generator 400 to the display panel 100 disposed on the cover panel 600.

FIG. 6 is a cross-sectional view illustrating an example of a sound generator of FIG. 5.

Referring to FIG. 6, the sound generator 400 may be a piezoelectric element or piezoelectric actuator (e.g., a component that uses the piezoelectric effect) for vibrating the display panel 100 using a piezoelectric material that contracts or expands based on voltage. The sound generator 400 may receive driving voltages (e.g., from the sound driver 300 illustrated in FIG. 2) and cause vibration, thereby outputting sound. For example, the sound generator 400 may be disposed on a lower surface of the cover panel 600 (e.g., the lower surface 680_b of the shielding layer 680 of FIG. 5) through an adhesive layer AD1. The sound generator 400 may include a vibration layer 410, a first electrode 420, and a second electrode 430. In one aspect, the first electrode 420 may include a first stem electrode 422 and first branch electrodes 424, and the second electrode 430 may include a second stem electrode 432 and second branch electrodes 434.

The first electrode 420 may include a first stem electrode 422 and first branch electrodes 424. The first stem electrode 422 may be disposed on one side of the vibration layer 410 or on multiple sides of the vibration layer 410. The first branch electrodes 424 may extend from the first stem electrode 422. The first branch electrodes 424 may be arranged in a manner parallel to each other. For example, the first stem electrode 422 may extend in the third direction DR3, and the first branch electrodes 424 may extend from the first stem electrode 422 in a direction perpendicular to the third direction DR3.

The second electrode 430 may include a second stem electrode 432 and second branch electrodes 434. The second stem electrode 432 may be disposed on the other side of the vibration layer 410 or on multiple sides of the vibration layer 410. The first stem electrode 422 and the second stem electrode 432 might not overlap each other. The second branch electrodes 434 may extend from the second stem electrode 432. The second branch electrodes 434 may be arranged in a manner parallel to each other. For example, the second stem electrode 432 may extend in the third direction DR3, and the second branch electrodes 434 may extend from the second stem electrode 432 in a direction perpendicular to the third direction DR3.

The first branch electrodes 424 and the second branch electrodes 434 may be parallel to each other in one direction. In addition, the first branch electrodes 424 and the second branch electrodes 434 may be alternately disposed in the third direction DR3. For example, the first branch electrodes 424 and the second branch electrodes 434 may be repeatedly disposed in the order of the first branch electrode 424, the second branch electrode 434, the first branch electrode 424, the second branch electrode 434 in the third direction DR3.

A first driving voltage may be applied from the sound driver 300 (see FIG. 2) to the first electrode 420, and a second driving voltage may be applied from the sound driver 300 to the second electrode 430 to induce vibration in the vibration layer 410.

The vibration layer 410 may include a piezoelectric material configured to deform in response to the first driving voltage and second driving voltage applied to the first electrode 420 and second electrode 430, respectively. The piezoelectric material may be one of a polyvinylidene fluoride (“PVDF”) film, plumbium zirconate titanate (“PZT”), or an electroactive polymer.

The vibration layer 410 may be disposed between the first branch electrodes 424 and the second branch electrodes 434 in a horizontal direction parallel to a lower surface of the shielding layer 680 of the cover panel 600. The vibration layer 410 may contract or expand in in response to the first driving voltage applied to the first branch electrode 424 and the second driving voltage applied to the second branch electrode 434.

FIG. 7 illustrates the vibration of a vibration layer disposed between first branch electrodes and second branch electrodes of the sound generator. FIG. 8 and FIG. 9 are cross-sectional views illustrating the vibration of the display panel using the sound generator of FIG. 7.

Referring to FIGS. 7 to 9, embodiments of the disclosure illustrate when the polarity of the vibration layer 410 between the first branch electrodes 424 and the respective overlying second branch electrodes 434 has an upper direction (↑), as illustrated in FIG. 7, the vibration layer 410 may have a positive polarity in upper portions thereof adjacent to the second branch electrode 434 and a negative polarity in lower portions thereof adjacent to the first branch electrode 424. In addition, when where the polarity of the vibration layer 410 between the first branch electrodes 424 and the respective overlying second branch electrodes 434 has a lower direction (or is directed downward), the vibration layer 410 may have a negative polarity in upper portions thereof adjacent to the second branch electrode 434 and a positive polarity in lower portions thereof adjacent to the first branch electrode 424. The direction of the polarity of the vibration layer 410 may be determined by a poling process for applying an electric field to the vibration layer 410 using the first branch electrode 424 and the second branch electrode 434.

In an embodiment, when the polarity of the vibration layer 410 between the first branch electrodes 424 and the respective overlying second branch electrodes 434 has an upper direction (↑), and a negative first driving voltage is applied to the first branch electrodes 424 and a positive second driving voltage is applied to the second branch electrodes 434, the vibration layer 410 may contract based on a first force F1. The first force F1 may be a contraction force. In addition, when a positive first driving voltage may be applied to the first branch electrodes 424 and a negative second driving voltage may be applied to the second branch electrodes 434, the vibration layer 410 may expand based on a second force F2. The second force F2 may be an extension force.

When the first driving voltage applied to the first electrode 420 and the second driving voltage applied to the second electrode 430 alternately change from a positive polarity to a negative polarity, the vibration layer 410 may undergo repeated contraction and expansion. As a result, the sound generator 400 is able to generate mechanical vibration.

Since the sound generator 400 is disposed on the lower surface of the cover panel 600, the display panel 100 may vertically vibrate, as illustrated in FIGS. 8 and 9, in response to the contraction and the expansion of the vibration layer 410 of the sound generator 400. For example, the display panel 100 may vibrate a long a third direction D3. The vibration of the display panel 100 induced by the sound generator 400 may cause the display device DD to generate sound output.

As illustrated in FIGS. 8 and 9, the vibration of the display panel 100 results in temporary concave or convex deformation of the layered structure based on whether the vibration layer 410 undergoes contraction or expansion. The upper surface of the display panel 100 may locally bow inward or outward, forming a curved profile that corresponds to the direction of mechanical force. For example, the contraction force F1 is applied, the display panel 100, along with the protective film 500 and the cover panel 600, may bow inward to form a concave profile. Alternatively, when the extension force F2 is applied, the display panel 100 may bow outward, forming a convex shape. In some cases, the structure may remain substantially planar during vibration based on the stiffness and characteristics of the display panel 100, the protective film 500, and the cover panel 600.

For example, a sound pressure of the sound output generated by the display device DD may vary based on a transmission rate of the vibration generated from the sound generator 400. Since the vibration generated from the sound generator 400 is transmitted to the display panel 100 through the cover panel 600 and the protective film 500, the sound pressure of sound output generated by the vibration transmitted to the display panel 100 may vary based on the vibration transmission rate of the cover panel 600 and the protective film 500. The transmission rate may be affected by factors such as the material stiffness, damping properties, and thickness of the cover panel 600 and the protective film 500. In some cases, a lower transmission rate may result in reduced sound pressure level or a weaker feedback.

Referring back to FIGS. 3 and 5, in a comparative example in which the insert 690 is not disposed in the first area 1A and where the sound generator 400 is disposed, the vibration generated by the sound generator 400 may be significantly absorbed and lost in layers included in the cover panel 600 and having relatively small hardness (e.g., the adhesive layers and the cushion layer). However, according to embodiments of the present disclosure, in the first area 1A where the sound generator 400 is disposed, layers having relatively small hardness (including the upper adhesive layer 610, the first intermediate adhesive layer 630, the cushion layer 640, the second intermediate adhesive layer 650, and the lower adhesive layer 670) may be removed to form the trench T in the first area 1A, and the insert 690 having relatively large hardness may be disposed in the trench T. Accordingly, the loss of the vibration generated by the sound generator 400 may be reduced, and the transmission rate of the vibration transmitted from the sound generator 400 to the display panel 100 may be enhanced. For example, the cover panel 600 including the insert 690 may properly transmit vibration generated by the sound generator 400 to the display panel 100, and can minimize loss of sound pressure when outputting sound through the vibration of the display panel 100. Accordingly, the intensity of sound or haptic generated by the display device DD and the electronic device ED including the same may be enhanced.

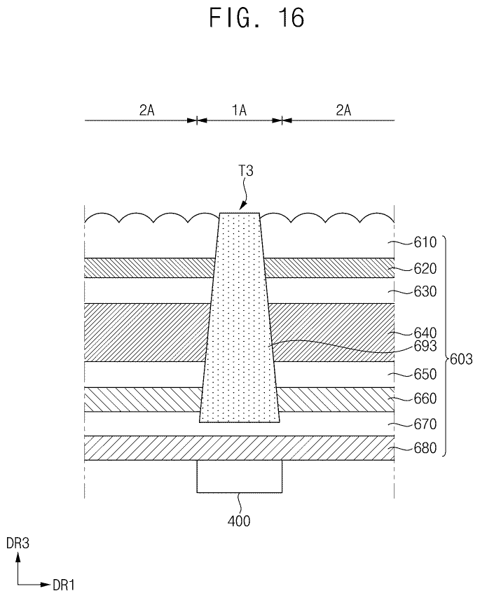

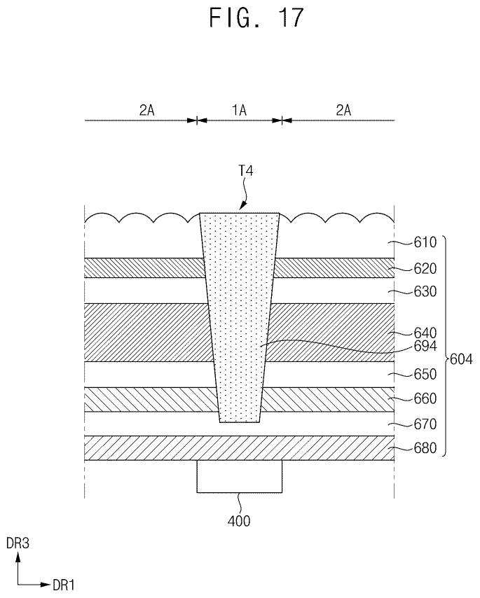

In an embodiment, the insert 690 may have a cross-sectional shape corresponding to a cross-sectional shape of the trench T. For example, a thickness of the insert 690 may be equal to the depth of the trench T. In addition, although FIG. 5 illustrates that the trench T and the insert 690 each have a rectangular cross-sectional shape, the present invention is not necessarily limited thereto, and the cross-sectional shapes of the trench T and the insert 690 may take alternative forms (see FIGS. 16 and 17). For example, the cross-sectional shapes of the trench T and the insert 690 may include trapezoidal, stepped, or curved profiles.

As illustrated in FIG. 5, the trench T may be formed from the upper surface of the upper adhesive layer 610 to a point between an upper surface 670_u of the lower adhesive layer 670 and a lower surface 670_b of the lower adhesive layer 670. For example, a thickness TH1 of the lower adhesive layer 670 in the first area 1A may be less than a thickness TH2 of the lower adhesive layer 670 in the second area 2A. For example, the thickness TH1 refers to the vertical distance between the lower surface 690_b of the insert 690 and the upper surface 680_u of the shielding layer 680 in the first area 1A. The thickness TH2 refers to the thickness of the lower adhesive layer 670 in the second area 2A where no trench is formed. In some cases, the thickness TH2 corresponds to the distance between the upper surface 670_u and the lower surface 670_b of the lower adhesive layer 670 in the second area 2A. In the first area 1A, the lower adhesive layer 670 may be disposed between a lower surface 690_b of the insert 690 and the upper surface 680_u of the shielding layer 680.

In an embodiment, the lower surface 690_b of the insert 690 may contact the upper surface 670_u of the lower adhesive layer 670 which represents the bottom surface T_b of the trench T. The contact surface may serve as a structural interface that defines the trench depth and provides stable support for the insert 690. The lower surface 690_b of the insert 690 may be spaced apart from the upper surface 680_u of the shielding layer 680 in the upper direction (e.g., in the third direction DR3). This spacing may reduce direct transmission of vibration into the shielding layer 680, thereby enhancing vibration confinement and enhancing energy transfer toward the display panel 100.

In an embodiment, an outer side surface of the insert 690 may contact the inner side surfaces of the upper adhesive layer 610, the first support layer 620, the first intermediate adhesive layer 630, the cushion layer 640, the second intermediate adhesive layer 650, and the second support layer 660 which represent the side surface T_s of the trench T. In an embodiment, the outer side surface of the insert 690 may further contact an inner side surface of the lower adhesive layer 670.

Since the lower surface 690_b of the insert 690 contacts the upper surface 670_u of the lower adhesive layer 670, and the outer side surface of the insert 690 contacts the inner side surfaces of the upper adhesive layer 610, the first intermediate adhesive layer 630, the second intermediate adhesive layer 650, and the lower adhesive layer 670, the insert 690 may be mechanically secured within the trench T and structurally coupled to multiple layers of the cover panel 600. In some cases, the lower surface 690_b of the insert 690 and the upper surface 670_u of the lower adhesive layer 670 may be at a same level. In some cases, the lower surface 690_b of the insert 690 may be at a lower level than the upper surface 670_u of the lower adhesive layer 670, but at a higher level than the lower surface 670_b of the lower adhesive layer 670.

In an embodiment, a distance D1 measured between the lower surface 680_b of the shielding layer 680 and the lower surface 690_b of the insert 690 in the first area 1A may be less than a distance D2 measured between the lower surface 680_b of the shielding layer 680 and the upper surface 670_u of the lower adhesive layer 670 in the second area 2A. Additionally, the distance D1 may be greater than a distance D3 measured between the lower surface 680_b of the shielding layer 680 and the lower surface 670_b of the lower adhesive layer 670 in the second area 2A. In some cases, the distance D3 may be measured between the lower surface 680_b of the shielding layer 680 and the upper surface 680_u of the shielding layer 680. In this configuration, D1 corresponds to the spacing between the shielding layer 680 and the insert 690. The distance D2 corresponds to the thickness of the lower adhesive layer 670 and shielding layer 680 in the second area 2A. The distance D3 corresponds to the thickness of the shielding layer 680 in the second area 2A.

In an embodiment, the level of the bottom surface T_b of the trench T in the first area 1A may be lower than a level of the upper surface 670_u of the lower adhesive layer 670 in the second area 2A, and may be higher than a level of the lower surface 670_b of the lower adhesive layer 670 in the second area 2A. For example, a level of the lower surface 690_b of the insert 690 in the first area 1A may be lower than the level of the upper surface 670_u of the lower adhesive layer 670 in the second area 2A, and may be higher than the level of the lower surface 670_b of the lower adhesive layer 670 in the second area 2A. Accordingly, the lower surface 690_b of the insert 690, which defines the bottom surface T_b of the trench T, may be located between the levels of the upper surface 670_u and the lower surface 670_b of the lower adhesive layer 670 in the second area 2A.

In an embodiment, the depth of the trench T may be less than a sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, the thickness of the second support layer 660 in the second area 2A, and the thickness of the lower adhesive layer 670 in the second area 2A.

In an embodiment, the thickness of the insert 690 in the first area 1A may be greater than a sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, and the thickness of the second support layer 660 in the second area 2A. In some cases, the thickness of the insert 690 in the first area 1A may be less than the sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, the thickness of the second support layer 660 in the second area 2A, and the thickness of the lower adhesive layer 670 in the second area 2A.

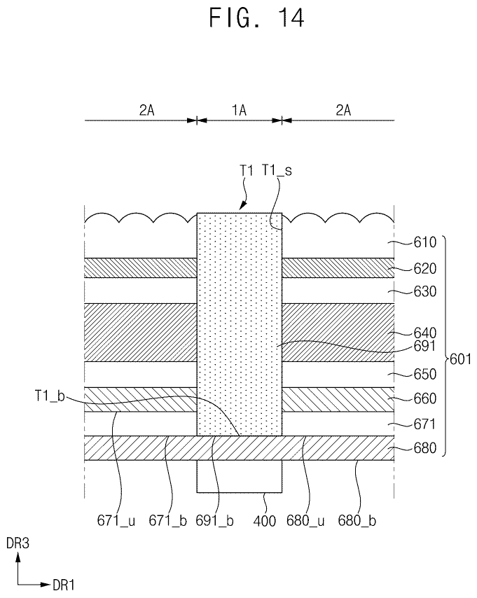

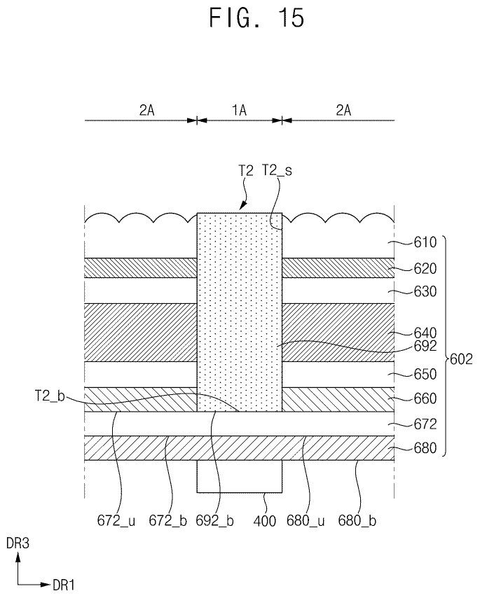

According to the embodiment of FIG. 5, the trench T may be formed by removing material from the upper adhesive layer 610 to an upper portion of the lower adhesive layer 670 in the first area 1A. The materials in these layers have a relatively small hardness, and the insert 690 having a relatively large hardness and may be disposed in the trench T. A lower portion of the lower adhesive layer 670 may not be removed, and the insert 690 may contact the remaining lower portion of the lower adhesive layer 670. Accordingly, compared to an embodiment in which the lower adhesive layer 670 is not removed in the first area 1A (see FIG. 15), the loss of the vibration by the cover panel 600 may be reduced. Compared to an embodiment in which the lower adhesive layer 670 is completely removed in the first area 1A (see FIG. 14), the insert 690 may be more reliably secured within the trench T and structurally coupled to surrounding layers of the cover panel 600.

As shown in FIG. 5, the insert 690 may form continuous contact with the surrounding inner wall surfaces of the trench T, enabling stable fixation and effective mechanical coupling with the stacked structure (e.g., the adhesive layer 610 to an upper portion of the lower adhesive layer 670). The insert 690 may have a tight clearance or press-fit geometry with the stacked structure to limit lateral movement under different loads or pressures. The material of the insert 690 may be selected for high stiffness and acoustic transmissibility to reduce energy loss through the surrounding layers (e.g., the adhesive layer 610 to an upper portion of the lower adhesive layer 670). These structural and material features may enhance the durability and performance of the sound generator 400 and the interface of the sound generator 400 with the display panel 100.

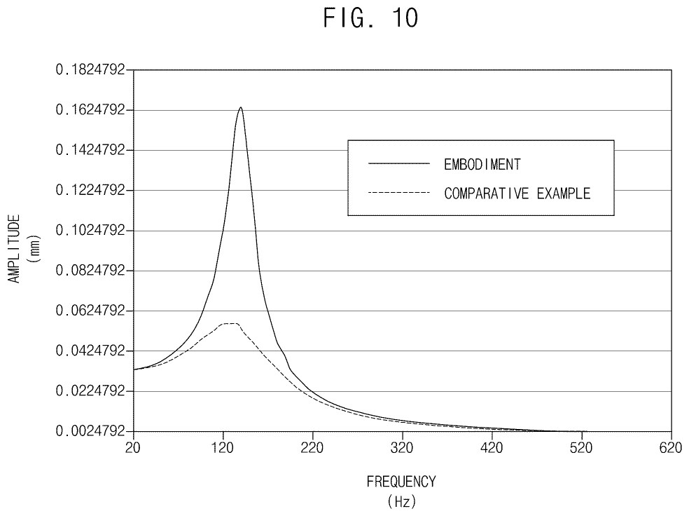

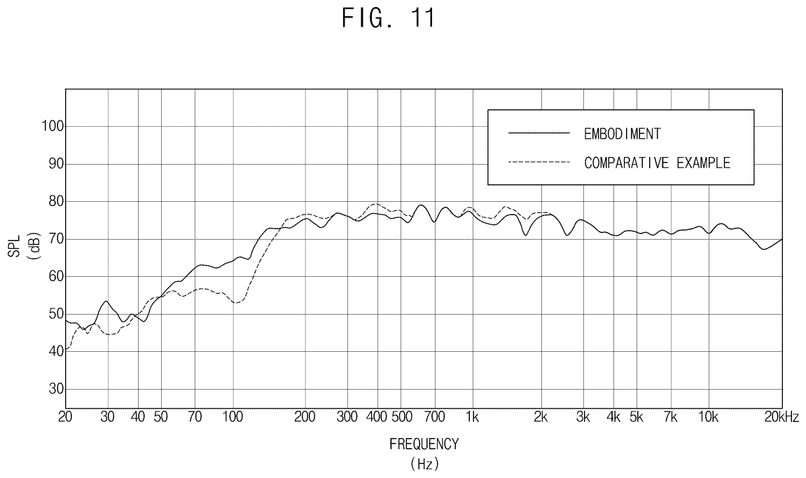

FIG. 10 is a graph illustrating an amplitude of vibration measured on an upper surface of a display panel. FIG. 11 is a graph illustrating a sound pressure level by frequency of sound generated from a display device.

FIG. 10 is a graph illustrating the amplitude of vibration measured on the upper surface of the display panel due to vibration of the sound generator in the display device including the insert 690, compared to a display device without the insert 690. FIG. 11 is a graph illustrating the sound pressure level (SPL) as a function of frequency, measured from sound generated by the sound generator 400 in the embodiment including the insert 690, compared to the comparative example without the insert 690.

Referring to FIG. 10, the display device DD including the insert 690 demonstrates an amplitude of vibration on the upper surface of the display panel increases by up to about three times within the audible frequency, compared to the display device of the comparative example that does not include the insert 690. In addition, referring to FIG. 11, the display device DD according to the embodiment including the insert 690 demonstrates that the sound pressure level increases by up to about 11 dB within the audible frequency, compared to the display device of the comparative example that does not include the insert 690. This enhancement is the result from the inclusion of the insert 690, having relatively large hardness, in the cover panel 600 of the display device DD, which may reduce the loss of the vibration generated by the sound generator 400 and enhance transmission efficiency to the display panel 100.

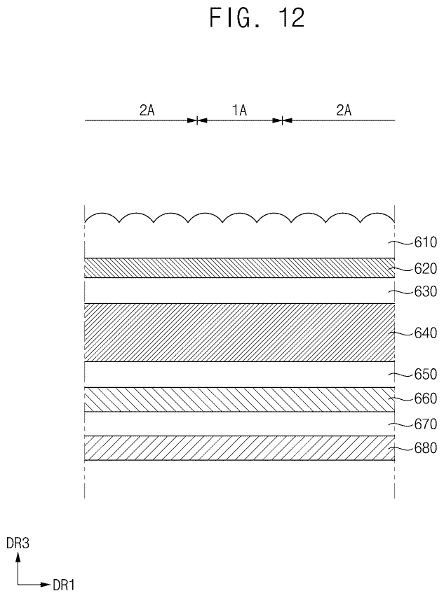

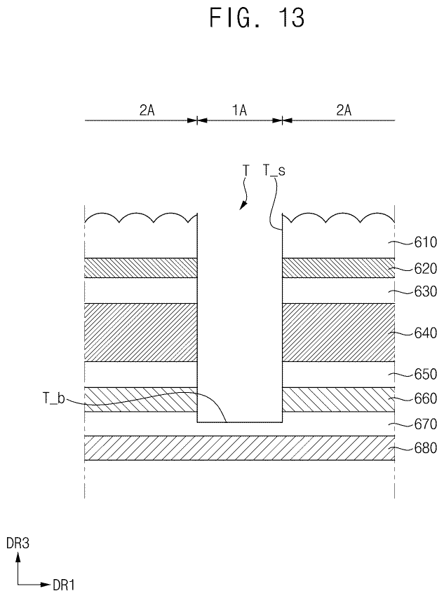

FIG. 12 and FIG. 13 are cross-sectional views illustrating an example of a method for manufacturing the cover panel of FIG. 5.

Referring to FIG. 12, the lower adhesive layer 670, the second support layer 660, the second intermediate adhesive layer 650, the cushion layer 640, the first intermediate adhesive layer 630, the first support layer 620, and the upper adhesive layer 610 may be sequentially stacked on the shielding layer 680 to form a stacked structure. This multilayer configuration may define the cover panel structure in the second area 2A, where no trench is formed. For example, the upper adhesive layer 610 may represent an uppermost layer of the cover panel 600, and the shielding layer 680 may represent a lowermost layer of the cover panel 600.

As illustrated in FIG. 13, in the first area 1A, a portion of the stacked structure from an upper surface of the laminated structure (e.g., the upper surface of the upper adhesive layer 610) in the thickness direction (e.g., in the direction opposite to the third direction DR3) may be removed to form the trench T. Then, the insert 690 having a shape corresponding to a shape of the trench T may be inserted into the trench T to manufacture the cover panel 600 of FIG. 5. In some cases, the trench T may be formed using one or more removal processes such as laser ablation, mechanical cutting, or chemical etching. In some cases, the trench T exposes a portion of the lower adhesive layer 670 (including an intermediate surface and side surfaces).

FIG. 14 is a cross-sectional view illustrating an example of a cover panel and a sound generator included in the electronic device of FIG. 3. FIG. 15 is a cross-sectional view illustrating an example of a cover panel and a sound generator included in the electronic device of FIG. 3.

Cover panels 601 and 602 of FIGS. 14 and 15 may be substantially the same as or similar to the cover panel 600 described above with reference to FIG. 5, except for depth of the trenches T1 and T2 and thickness of the inserts 691 and 692. Therefore, repeated description may be omitted or simplified.

Referring to FIG. 14, in an embodiment, the trench T1 may be formed from the upper surface of the upper adhesive layer 610 to the upper surface 680_u of the shielding layer 680. In the first area 1A, the trench T1 may expose the upper surface 680_u of the shielding layer 680. For example, the trench T1 may further penetrate (or extend through) the lower adhesive layer 671 in the thickness direction. The lower adhesive layer 671 may have a through hole corresponding to the first area 1A.

In an embodiment, the depth of the trench T1 may be equal to the sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, the thickness of the second support layer 660 in the second area 2A, and the thickness of the lower adhesive layer 671 in the second area 2A. The level of the bottom surface T1_b of the trench T1 in the first area 1A may be equal to the level of the upper surface 680_u of the shielding layer 680. For example, the bottom surface T1_b of the trench T1 in the first area 1A may coincide with the upper surface 680_u of the shielding layer 680.

In an embodiment, the thickness of the insert 691 may be equal to the sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, the thickness of the second support layer 660 in the second area 2A, and the thickness of the lower adhesive layer 671 in the second area 2A. The level of the lower surface 691_b of the insert 691 in the first area 1A may be equal to the level of the upper surface 680_u of the shielding layer 680. For example, the lower surface 691_b of the insert 691 in the first area 1A may coincide with the upper surface 680_u of the shielding layer 680.

In an embodiment, the lower surface 691_b of the insert 691 may contact the upper surface 680_u of the shielding layer 680 exposed by the trench T1. The outer side surface of the insert 691 may contact the inner side surfaces of the upper adhesive layer 610, the first support layer 620, the first intermediate adhesive layer 630, the cushion layer 640, the second intermediate adhesive layer 650, the second support layer 660, and the lower adhesive layer 671 which represent the side surface T1_s of the trench T1. Accordingly, the insert 691 may be fixed to the components of the cover panel 601. Through this stacking configuration, the insert 691 may be mechanically secured within the trench T1 and structurally coupled to the surrounding layers of the cover panel 601.

According to the embodiment of FIG. 14, the trench T1 may be formed by removing material from the upper adhesive layer 610 to the lower adhesive layer 670, which have a relatively small hardness, in the first area 1A, and the insert 691 having a relatively greater hardness may be disposed in the trench T1. For example, in the first area 1A where the sound generator 400 is disposed, the lower adhesive layer 671 having a relatively small hardness may be omitted, and the loss of the vibration by the cover panel 600 may be further reduced.

Referring to FIG. 15, in an embodiment, the trench T2 might not be formed in the lower adhesive layer 672. For example, the thickness of the lower adhesive layer 672 in the first area 1A may be the equal to the thickness of the lower adhesive layer 672 in the second area 2A. For example, the upper surface 672_u of the lower adhesive layer 672 may be generally flat in both the first area 1A and the second area 2A.

In an embodiment, the depth of the trench T2 may be equal to the sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, and the thickness of the second support layer 660 in the second area 2A. The level of the bottom surface T2_b of the trench T2 in the first area 1A may be equal to the level of the upper surface 672_u of the lower adhesive layer 672. For example, the bottom surface T2_b of the trench T2 in the first area 1A may coincide with the upper surface 672_u of the lower adhesive layer 672.

In an embodiment, the thickness of the insert 692 may be equal to the sum of the thickness of the upper adhesive layer 610 in the second area 2A, the thickness of the first support layer 620 in the second area 2A, the thickness of the first intermediate adhesive layer 630 in the second area 2A, the thickness of the cushion layer 640 in the second area 2A, the thickness of the second intermediate adhesive layer 650 in the second area 2A, and the thickness of the second support layer 660 in the second area 2A. The level of the lower surface 692_b of the insert 692 in the first area 1A may be equal to the level of the upper surface 672_u of the lower adhesive layer 672. For example, the lower surface 692_b of the insert 692 in the first area 1A may coincide with the upper surface 672_u of the lower adhesive layer 672.

Compared to the configuration shown in FIG. 15, in which the insert 692 ends at the upper surface 672_u of the lower adhesive layer 672, the configuration of FIG. 14, where the insert 691 extends to the shielding layer 680, may provide enhanced mechanical coupling and reduced vibration loss. The increased insertion depth in FIG. 14 may contribute to more effective transmission of vibrational energy from the sound generator 400 to the display panel 100.

FIG. 16 is a cross-sectional view illustrating an example of a cover panel and a sound generator included in the electronic device of FIG. 3. FIG. 17 is a cross-sectional view illustrating an example of a cover panel and a sound generator included in the electronic device of FIG. 3.

Cover panels 603 and 604 of FIGS. 16 and 17 may be substantially the same as or similar to the cover panel 600 described above with reference to FIG. 5, except for cross-sectional shapes of the trenches T3 and T4 and the inserts 693 and 694. Therefore, repeated description may be omitted or simplified.

Referring to FIG. 16, in an embodiment, the trench T3 may have a cross-sectional shape of a regular trapezoid in which a length of a bottom side is greater than a length of a top side. The insert 693 may have a cross-sectional shape corresponding to the cross-sectional shape of the trench T3. For example, the insert 693 may have a cross-sectional shape of a regular trapezoid in which a length of a bottom side is greater than a length of a top side. For example, the insert 693 may also have a regular trapezoidal cross-section with a wider base and a narrower top, conforming to the trench T3.

Referring to FIG. 17, in an embodiment, the trench T4 may have a cross-sectional shape of an inverted trapezoid in which a length of a bottom side is less than a length of a top side. The insert 694 may have a cross-sectional shape corresponding to the cross-sectional shape of the trench T4. For example, the insert 694 may have a cross-sectional shape of an inverted trapezoid in which a length of a bottom side is less than a length of a top side. For example, the insert 694 may also have an inverted trapezoidal cross-section with a narrower base and a wider top, conforming to the trench T4.

FIG. 18 is a cross-sectional view illustrating an example of a cover panel and a sound generator included in the electronic device of FIG. 3.

A cover panel 605 of FIG. 18 may be substantially the same as or similar to the cover panel 600 described above with reference to FIG. 5, except that a plurality of inserts 695a, 695b, 695c, and 695d are disposed to corresponding within the first area 1A. Therefore, repeated description may be omitted or simplified.

Referring to FIG. 18, in an embodiment, the cover panel 605 may have a plurality of trenches T5a, T5b, T5c, and T5d formed corresponding to one first area 1A. The trenches T5a, T5b, T5c, and T5d may be spaced apart from each other in the first direction DR1 in the first area 1A. For example, the first direction DR1 may be parallel to an upper surface of the shielding layer 680. For example, a sum of widths of the trenches T5a, T5b, T5c, and T5d in the first direction DR1 may be less than a width of the first area 1A in the first direction DR1.

The plurality of inserts 695a, 695b, 695c, and 695d may be disposed in the trenches T5a, T5b, T5c, and T5d, respectively. The inserts 695a, 695b, 695c, and 695d may be spaced apart from each other in the first direction DR1 in the first area 1A. For example, a sum of widths of the inserts 695a, 695b, 695c, and 695d in the first direction DR1 may be less than the width of the first area 1A in the first direction DR1. In some embodiments, the cover panel 605 may include a plurality of first areas 1A spaced apart from one another, with one insert provided in each first area 1A. In some embodiments, multiple inserts may be disposed within each of the plurality of first areas 1A.

FIG. 18 illustrates that the cover panel 605 includes four inserts 695a, 695b, 695c, and 695d corresponding to one first area 1A, but the present invention is not necessarily limited thereto, and the cover panel 605 may include two, three, or five or more inserts corresponding to one first area 1A. The number of inserts may be modified based on factors such as target vibration characteristics, spatial constraints, or structural reinforcement requirements.

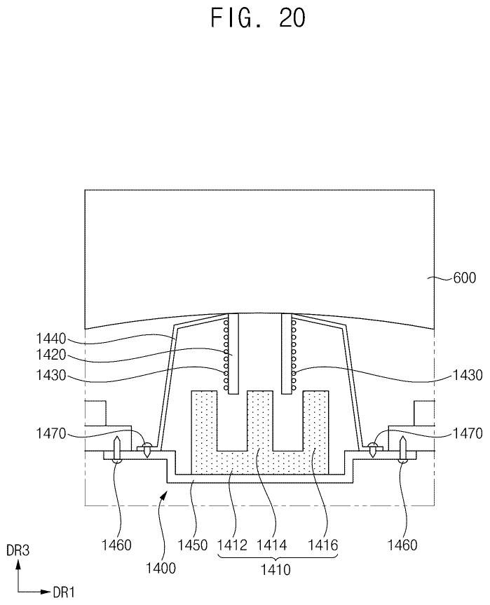

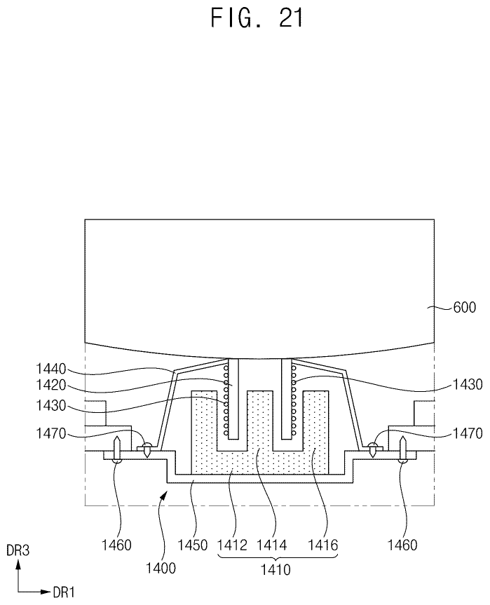

FIG. 19 is a cross-sectional view illustrating an example of a sound generator of FIG. 5. FIG. 20 and FIG. 21 are cross-sectional views illustrating the vibration of the display panel using the sound generator of FIG. 19. In some cases, FIG. 20 and FIG. 21 are cross-sectional views illustrating how the display panel vibrates in response to operation of the sound generator shown in FIG. 19.

Referring to FIGS. 19 to 21, the sound generator 1400 may include a magnet 1410, a bobbin 1420, a voice coil 1430, a damper 1440, a plate 1450, first fixing members 1460, second fixing members 1470, and a connecting member.

The magnet 1410 may be a permanent magnet, and a sintered magnet, such as barium ferrite may be used. The magnet 1410 may be formed as a ferric trioxide (Fe₂O₃) magnet, a barium carbonate (BaCO₃) magnet, a Nd magnet, a strontium ferrite magnet with an enhanced magnetic component, or an Al, Ni, or cobalt (Co) cast alloy magnet, but the present invention is not necessarily limited thereto. The Nd magnet may be, for example, a neodymium-iron-boron (Nd—Fe—B) magnet.

The magnet 1410 may include a flat portion 1412, a central protruding portion 1414 protruding from the center of the flat portion 1412, and a sidewall portion 1416 protruding from the edge of the flat portion 1412. The central protruding portion 1414 and the sidewall portion 1416 may be spaced apart from each other by a predetermined distance, and as a result, a predetermined space may be formed between the central protruding portion 1414 and the sidewall portion 1416.

The central protruding portion 1414 of the magnet 1410 may have N-pole magnetism, the flat portion 1412 and the sidewall portion 1416 may have S-pole magnetism. As a result, an external magnetic field may be formed between the central protruding portion 1414 and the flat portion 1412 of the magnet 1410, and between the central protruding portion 1414 and the sidewall portion 1416 of the magnet 1410.

The bobbin 1420 may be formed into a cylindrical shape. The central protruding portion 1414 of the magnet 1410 may be disposed in the bobbin 1420, and the bobbin 1420 may be disposed to surround the central protruding portion 1414 of the magnet 1410. The sidewall portion 1416 of the magnet 1410 may be disposed on the outside of the bobbin 1420. For example, the sidewall portion 1416 of the magnet 1410 may be disposed to surround the bobbin 1420. Spaces may be formed between the bobbin 1420 and the central protruding portion 1414 of the magnet 1410 and between the bobbin 1420 and the sidewall portion 1416 of the magnet 1410.

The bobbin 1420 may be formed of a pulp-or paper-processed material, aluminum (Al), magnesium (Mg), or an alloy thereof, a synthetic resin, such as polypropylene, or polyamide-based fibers, or the like.

The voice coil 1430 may be wound around the outer circumferential surface of the bobbin 1420. The voice coil 1430 may receive driving voltages, e.g., the first driving voltage and the second driving voltage, from the sound driver 300 (see FIG. 2).

The damper 1440 may be disposed between the bobbin 1420 and the plate 1450. The damper 1440 may surround the bobbin 1420, and may be fixed to the plate 1450 through the second fixing members 1470, such as screws.

The second fixing members 1470 may be inserted and fixed in holes formed in the damper 1440 and fixing holes formed in the plate 1450. The holes of the damper 1440 and the fixing holes of the plate 1450 may be screw holes into which screws can be fastened.

The damper 1440 may have elasticity and may be formed of a conductive material. The damper 1440 may control the vertical vibration of the bobbin 1420 while contracting or expanding based on the vertical movement of the bobbin 1420. For example, since the damper 1440 is connected to the bobbin 1420 and the plate 1450, the vertical movement of the bobbin 1420 may be limited by the restoring force of the damper 1440. For example, if the bobbin 1420 vibrates beyond or below a predetermined height, the bobbin 1420 can return to the original location due to the restoring force of the damper 1440.

The plate 1450 may be disposed on the bottom surface of the magnet 1410. The plate 1450 may be formed in one integral body with the magnet 1410 or may be formed as a separate element from the magnet 1410. The plate 1450 may be fixed through the first fixing members 1460.

One end of the voice coil 1430 may receive the first driving voltage from the sound driver 300 (see FIG. 2). The other end of the voice coil 1430 may receive the second driving voltage from the sound driver 300. A current may flow in the voice coil 1430 based on the first or second driving voltage. An applied magnetic field may be formed around the voice coil 1430 based on the current that flows in the voice coil 1430. For example, the direction of the current that flows in the voice coil 1430 when the first driving voltage is a positive voltage and the second driving voltage is a negative voltage may be opposite to the direction of the current that flows in the voice coil 1430 when the first driving voltage is a negative voltage and the second driving voltage is a positive voltage. As the first and second driving voltages are alternately driven, the N pole and the S pole of the applied magnetic field may be changed so that an attracting force and a repulsive force can be alternately acted upon the magnet 1410 and the voice coil 1430. Accordingly, as illustrated in FIGS. 20 and 21, the bobbin 1420 having the voice coil 1430 wound therearound may reciprocate in the third direction DR3. Therefore, the cover panel 600 and the display panel 100 on the cover panel 600 (see FIG. 5) may vibrate in the third direction DR3, and as a result, sound may be output. In some cases, the reciprocating motion may cause the cover panel 600 and the display panel 100 disposed on the cover panel 600 (see FIG. 5) to vibrate in the third direction DR3, thereby generating and outputting sound.

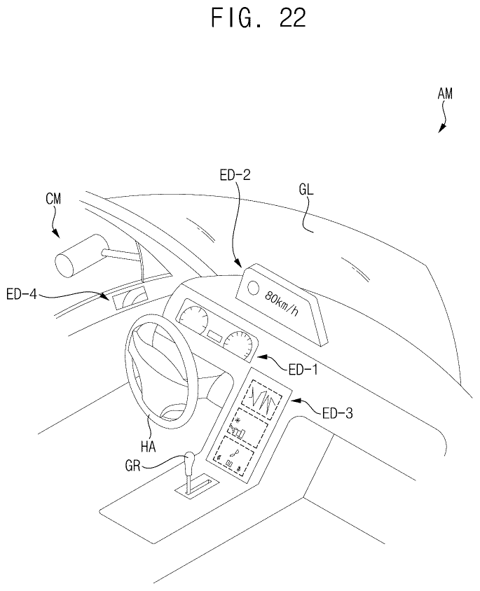

FIG. 22 is a drawing illustrating a vehicle including an electronic device according to an embodiment.

FIG. 22 is a diagram illustrating a vehicle AM in which first to fourth electronic devices ED-1, ED-2, ED-3, and ED-4 are disposed. At least one of the first to fourth electronic devices ED-1, ED-2, ED-3, and ED-4 may correspond to the electronic device ED described above with reference to FIGS. 1 to 21.

FIG. 22 illustrates a car as the vehicle AM, but this is merely an example, and the first to fourth electronic devices ED-1, ED-2, ED-3, and ED-4 may be disposed in other transportation vehicles, such as a bicycle, a motorcycle, a train, a boat, and an airplane. The scope of application is not necessarily limited to the illustrated examples.

Referring to FIG. 22, the vehicle AM may include a steering wheel HA and a gear GR for operating the vehicle AM, and a front window GL facing a driver may be disposed.

The first electronic device ED-1 may be disposed in a first region overlapping the steering wheel HA. For example, the first electronic device ED-1 may be a digital cluster that displays first information of the vehicle AM. The first information may include a first scale indicating a driving speed of the vehicle AM, a second scale indicating a number of revolutions of an engine (RPM (revolutions per minute)), an image indicating a fuel condition, or other types of vehicle operation data. The first scale and the second scale may be displayed as digital images.

The second electronic device ED-2 may be disposed in a second region facing a seat of the driver and overlapping the front window GL. The seat may be a seat in which the steering wheel HA is disposed. For example, the second electronic device ED-2 may be a head-up display (“HUD”) that displays second information of the vehicle AM. The second electronic device ED-2 may be optically transparent. The second information may include a digital number representing the driving speed of the vehicle AM, and may further include information such as current time or other real-time vehicle operation metrics. In an embodiment, the second information of the second electronic device ED-2 may be projected and displayed on the front window GL.

The third electronic device ED-3 may be disposed in a third region adjacent to the gear GR. For example, the third electronic device ED-3 may be a center information display (“CID”) which is disposed between the seat of the driver and a seat of a passenger, and displays third information. The seat for the passenger may be a seat spaced apart from the seat for the driver with the gear GR therebetween. The third information may include information related to street conditions (e.g., navigation information), playing of music or a radio broadcast, reproduction of a dynamic video (or image), an internal temperature of the vehicle AM, or other vehicle system and entertainment-related information.

The fourth electronic device ED-4 may be disposed in a fourth region spaced apart from the steering wheel HA and the gear GR, and adjacent to a side part of the vehicle AM. For example, the fourth electronic device ED-4 may be a digital side-view mirror that displays fourth information. The fourth electronic device ED-4 may display an external image of the vehicle AM captured by a camera module CM disposed outside of the vehicle AM. The fourth information may include the external image of the vehicle AM.

The positions of the first to fourth electronic devices ED-1, ED-2, ED-3, and ED-4 illustrated in FIG. 8 are exemplary illustrated, and may thus be changed to other positions based on a user convenience. In addition, the first to fourth information described above are examples, and the first to fourth electronic devices ED-1, ED-2, ED-3, and ED-4 may further display information pertaining to the inside and outside of the vehicle. The first to fourth information may include pieces of information different from each other. However, the present invention is not necessarily limited thereto, and part of the first to fourth information may include information identical to each other.

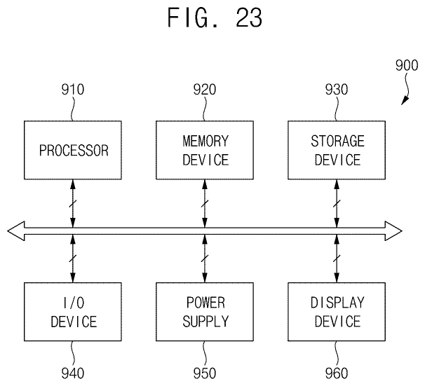

FIG. 23 is a block diagram illustrating an electronic device according to an embodiment. In some cases, the electronic device 900 may be implemented in a smart phone, a tablet, a wearable device, a laptop computer, a television, a navigation system, a home appliance, a kiosk, or an in-vehicle infotainment system. The configuration of the electronic device 900 may also be applied to industrial equipment, smart signage, or other computing-based platforms requiring display output and signal processing.

Referring to FIG. 23, in an embodiment, an electronic device 900 (the electronic device ED of FIG. 2) may include a processor 910, a memory device 920, a storage device 930, an input/output (“I/O”) device 940, a power supply 950, and a display device 960. For example, the processor 910 may be the processor PCS of FIG. 2, and the display device 960 may be the display device DD of FIG. 2. The electronic device 900 may further include a plurality of ports for communicating with a video card, a sound card, a memory card, a universal serial bus (“USB”) device, or other external input/output interfaces.

The processor 910 may perform various computing functions. The processor 910 may be coupled to other components via an address bus, a control bus, a data bus, or other communication interfaces suitable for internal data transfer. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. For example, power supply 950 may include a battery. The display device 960 may be coupled to other components via the buses or other communication links. In an embodiment, the display device 960 may be included in the I/O device 940. For example, the display device 960 may be an example of, or includes aspects of, the display device DD described with reference to FIGS. 1-21.

Although embodiments and implementations have been described herein, other embodiments and modifications may be apparent from this description. Accordingly, the invention is not necessarily limited to such embodiments, but rather to the broader scope of the appended claims and various obvious modifications and equivalent arrangements as would be apparent to a person of ordinary skill in the art.

What is claimed is:

1. A cover panel comprising:
a shielding layer including a first area and a second area surrounding the first area;
a lower adhesive layer disposed on the shielding layer;
a cushion layer disposed on the lower adhesive layer;
an upper adhesive layer disposed on the cushion layer;
a trench formed in the first area, wherein the trench penetrates the upper adhesive layer and the cushion layer; and
an insert disposed in the trench, wherein the insert includes a material different from a material of the cushioning layer, a material of the upper adhesive layer, and a material of the lower adhesive layer.

2. The cover panel of claim 1, wherein a hardness of the insert is greater than each of a hardness of the cushion layer, the upper adhesive layer, and the lower adhesive layer.

3. The cover panel of claim 1, wherein a thickness of the insert in the first area is greater than a sum of a thickness of the upper adhesive layer, a thickness of the cushion layer, and a thickness of the lower adhesive layer in the second area.

4. The cover panel of claim 1, wherein an outer side surface of the insert contacts an inner side surface of the trench.

5. The cover panel of claim 1, wherein a lower surface of the insert is spaced apart from an upper surface of the shielding layer, and
wherein the lower adhesive layer is disposed between the lower surface of the insert and the upper surface of the shielding layer.

6. The cover panel of claim 5, wherein in the first area, the lower surface of the insert contacts an upper surface of the lower adhesive layer.

7. The cover panel of claim 5, wherein a thickness of the lower adhesive layer in the first area is less than a thickness of the lower adhesive layer in the second area.

8. The cover panel of claim 5, wherein a first distance between a lower surface of the shielding layer and the lower surface of the insert in the first area is less than a second distance between the lower surface of the shielding layer and an upper surface of the lower adhesive layer in the second area, and the first distance is greater than a third distance between the lower surface of the shielding layer and a lower surface of the lower adhesive layer in the second area.

9. The cover panel of claim 5, wherein a thickness of the lower adhesive layer in the first area is equal to a thickness of the lower adhesive layer in the second area.

10. The cover panel of claim 1, wherein the trench penetrates the lower adhesive layer, and
wherein a lower surface of the insert contacts an upper surface of the shielding layer.

11. The cover panel of claim 10, wherein a side surface of the insert contacts a side surface of the lower adhesive layer.

12. The cover panel of claim 1, further comprising:
a first support layer disposed between the upper adhesive layer and the cushion layer; and
a first intermediate adhesive layer disposed between the first support layer and the cushion layer,
wherein the trench penetrates the first support layer and the first intermediate adhesive layer in the first area, and
wherein a thickness of the insert in the first area is greater than a sum of a thickness of the upper adhesive layer in the second area, a thickness of the first support layer in the second area, a thickness of the first intermediate adhesive layer in the second area, and a thickness of the cushion layer in the second area.

13. The cover panel of claim 12, further comprising:
a second support layer disposed between the lower adhesive layer and the cushion layer; and
a second intermediate adhesive layer disposed between the second support layer and the cushion layer,
wherein the trench penetrates the second support layer and the second intermediate adhesive layer in the first area, and
wherein the thickness of the insert in the first area is greater than a sum of the thickness of the upper adhesive layer in the second area, the thickness of the first support layer in the second area, the thickness of the first intermediate adhesive layer in the second area, the thickness of the cushion layer in the second area, a thickness of the second intermediate adhesive layer in the second area, and a thickness of the second support layer in the second area.

14. The cover panel of claim 1, wherein the trench and the insert each have a rectangular cross-sectional shape.

15. The cover panel of claim 1, wherein the trench and the insert each have a trapezoidal cross-sectional shape.

16. The cover panel of claim 1, wherein:
the trench comprises a plurality of trenches spaced apart from each other in the first area, and
wherein the insert includes a plurality of inserts respectively disposed in the plurality of trenches.

17. A display device comprising:
a cover panel including a first area and a second area surrounding the first area;
a display panel disposed on the cover panel, and including a plurality of pixels; and
a sound generator disposed under the cover panel in the first area, and configured to transmit vibration to the display panel,
wherein the cover panel includes:
a shielding layer;
a lower adhesive layer disposed on the shielding layer;
a cushion layer disposed on the lower adhesive layer;
an upper adhesive layer disposed on the cushion layer;
a trench formed in the first area, wherein the trench penetrates the upper adhesive layer and the cushion layer; and
an insert disposed in the trench in the first area, wherein the insert includes a material different from a material of the cushioning layer, a material of the upper adhesive layer, and a material of the lower adhesive layer.

18. The display device of claim 17, wherein a hardness of the insert is greater than a hardness of the cushion layer, the upper adhesive layer, and the lower adhesive layer.

19. The display device of claim 17, wherein the sound generator overlaps the insert in the first area.

20. An electronic device comprising:
a cover panel including a first area and a second area surrounding the first area;
a display panel disposed on the cover panel, and including a plurality of pixels;
a sound generator disposed under the cover panel in the first area, and configured to generate vibration and to transmit the vibration to the display panel; and
a housing contains the cover panel, the display panel, and the sound generator,
wherein the cover panel includes:
a shielding layer;
a lower adhesive layer disposed on the shielding layer;
a cushion layer disposed on the lower adhesive layer;
an upper adhesive layer disposed on the cushion layer;
a trench formed in the first area, wherein the trench penetrates the upper adhesive layer and the cushion layer; and
an insert disposed in the trench in the first area, wherein the insert includes a material different from a material of the cushioning layer, a material of the upper adhesive layer, and a material of the lower adhesive layer.
